(19) United States
(12) Patent Application Publication
(10) Pub. No.: US 2012/0268897 A1
(43) Pub. Date: Oct. 25, 2012

(54) ELECTRONIC DEVICE ENCLOSURE

(75) Inventor: Gang-Qiang QIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/425,388

(22) Filed: Mar. 20, 2012

(30) Foreign Application Priority Data
Apr. 20, 2011 (CN) 201110099335.X

(51) Int. Cl. H05K 7/16

(52) U.S. Cl. 361/725

(57) ABSTRACT

An electronic device enclosure includes an enclosure, and a mounting member. The enclosure includes a front wall and a door rotatably attached to the front wall. The mounting member includes a first mounting panel and a second mounting panel. The mounting member is rotatable relative to the front wall and positioned in a first position or a second position, when the mounting member is located in the first position, the second mounting panel is above the first mounting member, and the second mounting panel abuts the door, preventing the door from rotating relative to the front wall; when the mounting member is located in the second position, the second mounting panel is below the first panel to be disengaged from the door, and the door is opened relative to the front wall.

### BACKGROUND

1. Technical Field

The present disclosure relates to electronic device enclosures, more particularly to an electronic device enclosure for data center servers.

2. Description of Related Art

Blade and rack-mounted servers are popularly used in data center servers. In order to achieve high performance, many rack-mounted servers may be clustered in an enclosure. A door is defined in the enclosure for the rack-mounted servers to put into or be taken out of the enclosure. However, the door may be accidentally opened when the enclosure is being transported. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device enclosure in accordance with an embodiment.

FIG. 2 is an exploded, cut-away view of FIG. 1.

FIG. 3 is an assembled view of FIG. 2, and a mounting member of the electronic device is located in a first position.

FIG. 4 is a partially cross-sectional view of FIG. 3 along line IV-IV.

FIG. 5 is similar to FIG. 3, and the mounting member is located in a second position.

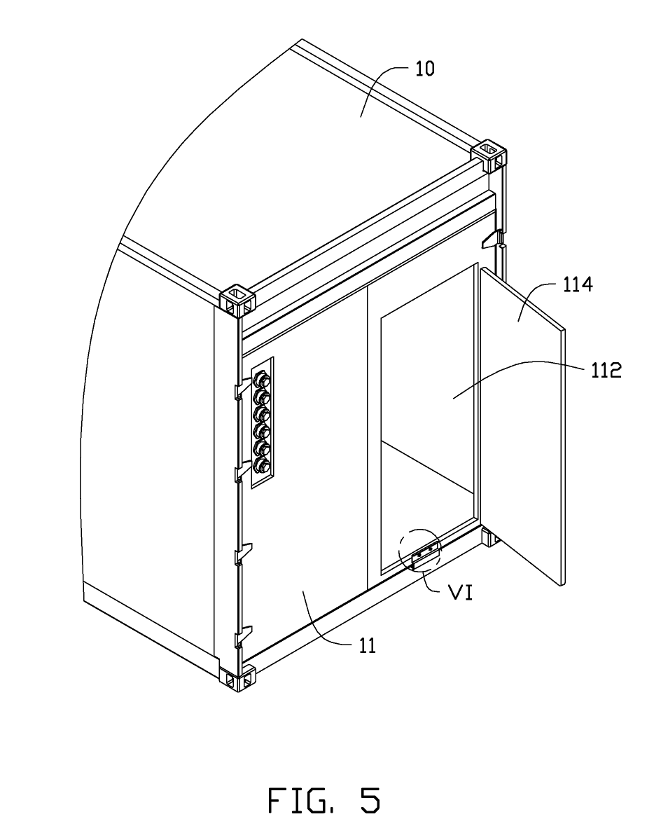

FIG. 6 is a partially cross- sectional view of FIG. 5 along line VI-VI.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

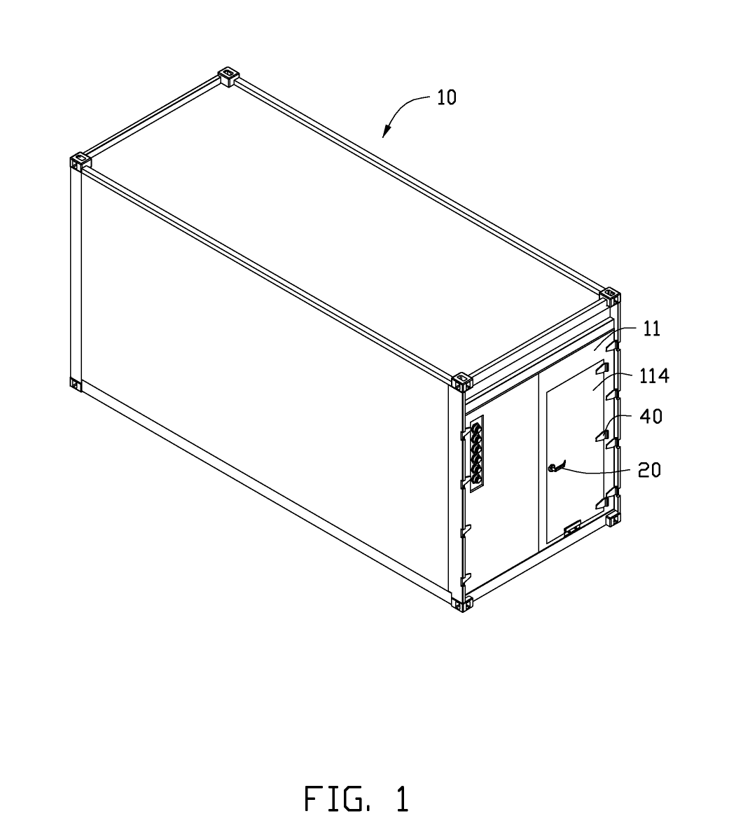

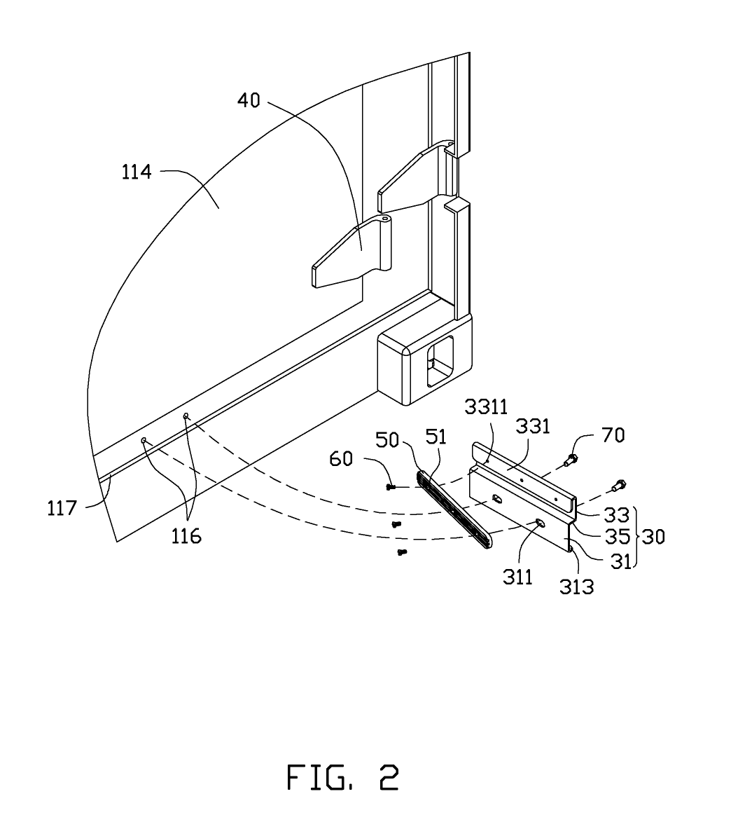

FIGS. 1 and 2, show an electronic device enclosure in accordance with an embodiment including an enclosure 10 and a mounting member 30 attached to the enclosure 10. In one embodiment, the enclosure 10 is a container for receiving blade and rack-mounted servers.

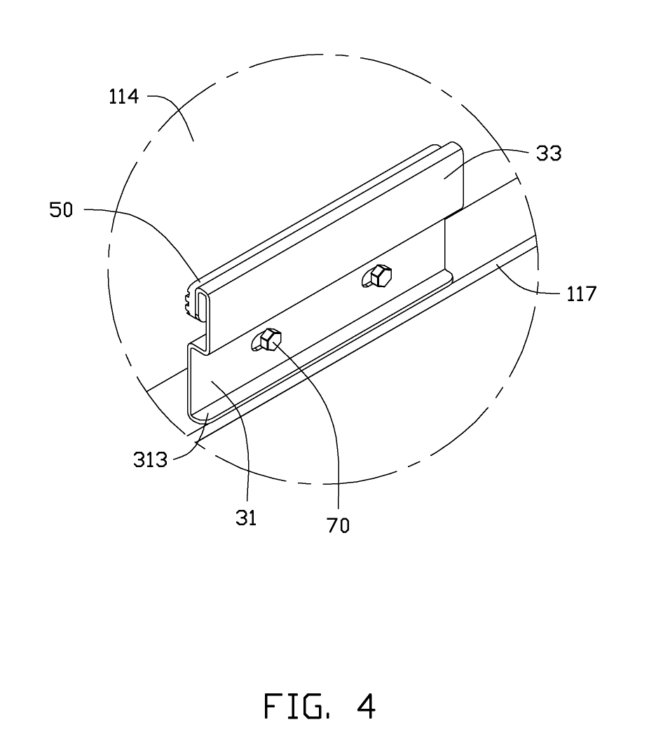

The enclosure 10 includes a front wall 11. The front wall 11 defines an opening 112 (shown in FIG. 4) for blade and rack-mounted servers to be put in or taken out of the enclosure 10. A door 114 is rotatably secured to the front wall 11 by a plurality of rotatable members 40. The door 114 includes a lock 20 to lock the door 114 on the front wall 11. Two securing holes 116 are defined in the front wall 11 below the opening 112.

The front wall 11 further comprises a step 117 below the two securing holes 116.

The mounting member 30 includes a first mounting panel 31, a second mounting panel 33, and a connecting panel 35 connected to the first mounting panel 31 and the second mounting panel 33. In one embodiment, the connecting panel 35 is substantially perpendicular to the first mounting panel 31 and the second mounting panel 33, the first mounting panel 31 is substantially parallel to the connecting panel 35, and an extending direction of the first mounting panel 31 is opposite to that of the second mounting panel 33.

The first mounting panel 31 defines two mounting holes 311 corresponding to the two securing holes 116. A flange 313 extends from a bottom edge of the first mounting panel 31, to be attached to the step 117. In one embodiment, the flange 313 is substantially perpendicular to the first mounting panel 31.

An extending panel 331 extends from a top edge of the second mounting panel 33, and three positioning holes 3311 are defined in the extending panel 331. In one embodiment, the extending panel 331 is substantially parallel to the second mounting panel 33, and an extending direction of the extending panel 331 is same as that of the second mounting panel 33.

A vibration-absorbing member 50 is attached to the second mounting panel 33.

Three through holes 51 are defined in the vibration-absorbing member 50 and corresponding to the three positioning holes 3311. Three fixing members 60, such as screws, are inserted into the three positioning holes 3311 and the three through holes 51, to mount the vibration-absorbing member 50 to the second mounting panel 33. In one embodiment, the vibration-absorbing member 50 is plastic.

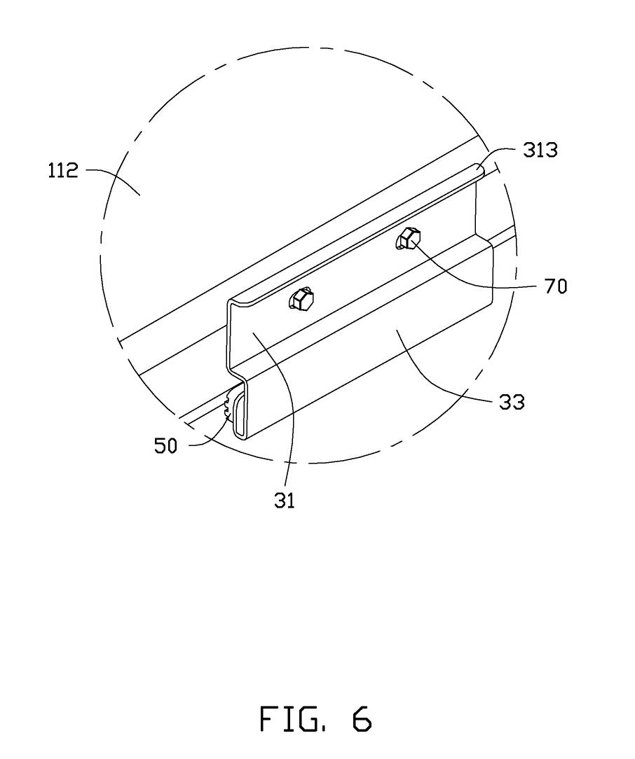

The mounting member 30 can be positioned in a first position (shown in FIG. 4) or in a second position (shown in FIG. 6). When the mounting member 30 is located in the first position, the second mounting panel 33 is above the first mounting panel 31, and the flange 313 abuts the step 117. When the mounting member 30 is located in the second position, the second mounting panel 33 is below the first mounting panel 31.

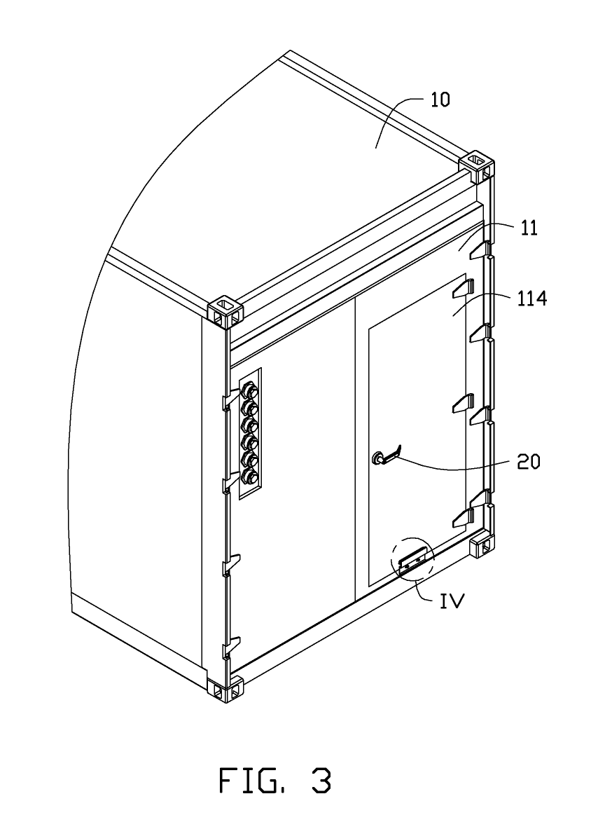

Referring to FIGS. 3-4, when the enclosure 10 is transported, the door 114 is locked to the front wall 11. The mounting member 30 abuts the front wall 11 and the door 114. The two mounting holes 311 are aligned with the two securing holes 116. Two positioning members 70 are engaged in the two mounting holes 311 and the two securing holes 116, to secure the mounting member 30 to the front wall 11. The mounting member 30 is located in the first position, the second mounting panel 33 is above the first mounting panel 31. The second mounting panel 33 with the vibration-absorbing member 50 abuts the front wall 11, to prevent the door 114 from disengaging from the front wall 11.

Referring to FIGS. 6, when the door 114 needs to be opened. The two positioning members 70 are detached from the mounting member 30. The mounting member 30 is rotated about 180° from the first position to be in the second position. The second mounting panel 33 is below the first mounting panel 31, so the second mounting panel 33 can be disengaged from the door 114. The two positioning members 70 are fixed to the two mounting holes 311 and the two securing holes 116 again, to secure the mounting member 30 to the front wall. Thus, the door 114 can be opened.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
an enclosure comprising a front wall and a door rotatably attached to the front wall;
a mounting member comprising a first mounting panel and a second mounting panel;
wherein the mounting member is rotatable relative to the front wall and positioned in a first position or a second position, when the mounting member is located in the first position, the second mounting panel is above the first mounting member, and the second mounting panel abuts the door such that the door is prevented from being rotated relative to the front wall; when the mounting member is located in the second position, the second mounting panel is below the first panel to be disengaged from the door, and the door is opened relative to the front wall.

2. The electronic device enclosure of claim 1, wherein the second mounting panel comprises an extending panel, and the extending panel abuts the door when the mounting member is located in the first position.

3. The electronic device enclosure of claim 1, comprises a vibration-absorbing member, and the vibration-absorbing member is attached to the extending panel.

4. The electronic device enclosure of claim 3, wherein a length and a width of the vibration-absorbing member are same as a length and a width of the extending panel.

5. The electronic device enclosure of claim 1, wherein mounting member further comprises a connecting panel connected to the first mounting panel and the second mounting panel, and the connecting panel is substantially perpendicular to the first mounting panel and the second mounting panel.

6. The electronic device enclosure of claim 1, wherein the front wall further comprises a step, the mounting member further comprises a flange extending from the first mounting panel, and the first mounting panel abuts the step when the mounting member is located in the first position.

7. The electronic device enclosure of claim 6, wherein the flange is substantially perpendicular to the first mounting panel.

8. The electronic device enclosure of claim 6, wherein the front wall defines two securing holes located between the door and the step, the mounting member comprises two positioning members secured to the first mounting panel, and each of the two position members is engaged in each of the two securing holes.

9. The electronic device enclosure of claim 8, wherein the first mounting panel defines two mounting holes to receive the two positioning members, and the two positioning members are removable to be disengaged from the two mounting holes.

10. An electronic device enclosure comprising:
an enclosure comprising a front wall and a door rotatably attached to the front wall; the front wall defining two securing holes below the door;
a mounting member attached to the front wall and comprising a first mounting panel, a second mounting panel, and two positioning members attached to the first mounting panel; wherein each of the two positioning members is engaged in each of the two securing holes such that the mounting member is secured to the front wall, and the second mounting panel abuts the door to prevent the door from being rotated relative to the front wall;
wherein the two positioning members are removable from the two securing holes, and the mounting member is rotatable relative to the front wall to disengage the second mounting panel from the door.

11. The electronic device enclosure of claim 10, wherein the second mounting panel comprises an extending panel, and the extending panel abuts the door.

12. The electronic device enclosure of claim 10, comprises a vibration-absorbing member, and the vibration-absorbing member is attached to the extending panel.

13. The electronic device enclosure of claim 12, wherein a length and a width of the vibration-absorbing member are same as a length and a width of the extending panel.

14. The electronic device enclosure of claim 10, wherein mounting member further comprises a connecting panel connected to the first mounting panel and the second mounting panel, and the connecting panel is substantially perpendicular to the first mounting panel and the second mounting panel.

15. The electronic device enclosure of claim 10, wherein the front wall further comprises a step, the mounting member further comprises a flange extending from the first mounting panel, and the first mounting panel abuts the step when the second mounting panel abuts the door.

16. The electronic device enclosure of claim 15, wherein the flange is substantially perpendicular to the first mounting panel.
